(19) United States
(12) Patent Application Publication
(10) Pub. No.: US 2006/0065421 A1
(43) Pub. Date: Mar. 30, 2006

(54) Circuit device and manufacturing method thereof

(75) Inventors: Kazumasa Arai, Seta-gun (JP); Yutaka Kubota, Ota-city (JP); Yusuke Igarashi, Isesaki-city (JP); Hidefumi Saito, Isesaki-city (JP); Masami Motegi, Ora-gun (JP); Noriaki Sakamoto, Yamada-gun (JP)

Correspondence Address: WATCHSTONE P + D, 1300 EYE STREET, NW, 400 EAST TOWER, WASHINGTON, DC, 20005, US

(73) Assignees: SANYO ELECTRIC CO., LTD., Moriguchi-city (JP); Kanto SANYO Semiconductors Co., Ltd., Ora-gun (JP)

(21) Appl. No.: 11/237,856

(22) Filed: Sep. 29, 2005

(30) Foreign Application Priority Data
Sep. 30, 2004 (JP) 2004-288213

(51) Int. Cl. H05K 5/06

(52) U.S. Cl. 174/52.2

(57) ABSTRACT

Warping of a hybrid integrated circuit device 10 due to shrinkage on curing of a sealing resin 14 is suppressed. The hybrid integrated circuit device 10 includes: a conductive pattern 13 provided on a surface of a circuit board 11; circuit elements 15 fixed to the conductive pattern 13; thin metal wires 17 electrically connecting the circuit elements 15 to the conductive pattern; leads 16 which are connected to the conductive pattern 13 to become output or input and extended to the outside; and a sealing resin 14 which is made of a thermosetting resin and covers the circuit board 11 by transfer molding while at least a rear surface of the circuit board is exposed. Here, a thermal expansion coefficient of the sealing resin 14 is set to be smaller than a thermal expansion coefficient of the circuit board 11. Thus, warping of the circuit board 11 in an after cure step can be prevented.

Priority is claimed to Japanese Patent Application Number JP2004-288213 filed on Sep. 30, 2004, the disclosure of which is incorporated herein by reference in its entirety.

### BACKGROUND OF THE INVENTION

1. Field of the Invention

The preferred embodiment of the invention relates to a circuit device and a manufacturing method thereof, and more particularly relates to a circuit device in which warping of a substrate is reduced, the warping being caused by heat curing of a sealing resin, and a manufacturing method thereof.

2. Description of the Related Art

With reference to FIGS. 7A to 7C, a configuration of a conventional hybrid integrated circuit device 100 will be described.

With reference to FIG. 7A, a configuration of a conventional hybrid integrated circuit device 100A will be described. On a surface of a rectangular substrate 101, a conductive pattern 103 is formed with an insulating layer 102 interposed therebetween. A predetermined electrical circuit is formed by fixing circuit elements in desired spots of the conductive pattern 103. Here, as the circuit elements, a semiconductor element 105A and a chip element 105B are connected to the conductive pattern 103. A rear surface of the semiconductor element 105A is fixed to the conductive pattern 103 by use of a bond 106 such as solder. Electrodes on both ends of the chip element 105B are fixed to the conductive pattern 103 by use of the bond 106. A lead 104 is connected to the conductive pattern 103 formed on a peripheral part of the substrate 101, and functions as an external terminal.

However, the hybrid integrated circuit device 100A described above has a problem where a crack occurs in the bond 106 due to stress caused by a temperature change. This problem will be described by taking the chip element 105B for example. When aluminum is used as a material of the substrate 101, a thermal expansion coefficient of the substrate 101 is 23×10⁻⁶/° C. Meanwhile, the chip element 105B has a small thermal expansion coefficient. Specifically, a thermal expansion coefficient of a chip resistor is 7×10⁻⁶/° C., and a thermal expansion coefficient of a chip condenser is 10×10⁻⁶/° C. Therefore, there is a large difference in the thermal expansion coefficient between the chip element 105B and the substrate 101. Thus, in the temperature change, a large stress acts on the bond 106 which joins the element and the substrate together. Consequently, the crack occurs in the bond 106, and a problem of a connection failure arises.

With reference to FIG. 7B, description will be given of a structure that suppresses the crack in the bond 106. This technology is described for instance in Japanese Patent Application Publication No. Hei 5 (1993)-102645. Here, the chip element 105B and the bond 106 are covered with a covering resin 108. Here, a thermal expansion coefficient of the covering resin 108 is approximately equal to the thermal expansion coefficient (23×10⁻⁶/° C.) of the substrate 101 made of aluminum. Thus, the chip element 105B having the small thermal expansion coefficient is surrounded by the covering resin 108 having the thermal expansion coefficient substantially equal to that of the substrate 101 made of aluminum. Accordingly, the stress applied to the bond 106 in the temperature change can be reduced.

In a hybrid integrated circuit device 100C shown in FIG. 7C, the surface and sides of the substrate 101 are entirely covered with a sealing resin 109 having a thermal expansion coefficient that approximates that of the substrate 101. Here, the sealing resin 109 is formed by transfer molding.

However, when the surface of the substrate 101 is entirely sealed by use of the sealing resin 109 having the thermal expansion coefficient that approximates that of the substrate 101, there arises a problem that the substrate 101 is warped by shrinkage on curing of the sealing resin 109. This is caused by that the larger the thermal expansion coefficient of the sealing resin 109 is, the more an amount of the shrinkage on curing in heat curing is increased. Particularly, if a planar size of the substrate 101 is as large as about 6 cm×4 cm or more, this problem of warping noticeably occurs. Furthermore, as shown in FIG. 7C, if a rear surface of the substrate 101 is exposed from the sealing resin 109, a large shrinkage stress acts above the substrate 101. Thus, a strong bending stress acts on the substrate 101. Moreover, there is also a problem that large warping of the entire device makes it impossible to allow the device to come into contact with a radiator such as a radiation fin.

### SUMMARY OF THE INVENTION

A circuit device of the present invention, which includes a conductive pattern provided on a surface of a circuit board, circuit elements electrically connected to the conductive pattern, and a sealing resin which seals the circuit elements by covering at least the surface of the circuit board, wherein a thermal expansion coefficient of the sealing resin is set to be smaller than a thermal expansion coefficient of the circuit board in a manner that a filler is mixed in the resin.

A method for manufacturing a circuit device of the present invention includes: forming an electrical circuit on a surface of a circuit board, the electrical circuit including a conductive pattern and circuit elements; and covering at least the surface of the circuit board with a sealing resin having a filler mixed therein so as to cover the circuit elements. In the method, the sealing resin having a thermal expansion coefficient smaller than that of the circuit board is used.

Furthermore, a method for manufacturing a circuit device of the present invention includes: forming an electrical circuit on a surface of a circuit board, the electrical circuit including a conductive pattern and circuit elements; covering at least the surface of the circuit board with a sealing resin having a filler mixed therein so as to cover the circuit elements; curing the sealing resin in a manner that the circuit board is curved toward a rear surface thereof by heating the sealing resin; and allowing any of the sealing resin and the rear surface of the circuit board to come into contact with a surface of a radiator in a manner that curve of the circuit board is reduced.

Furthermore, a method for manufacturing a circuit device of the present invention includes: preparing a substrate made of any of aluminum and copper, in which a conductive pattern mainly made of copper is formed; mounting circuit elements on the substrate; and forming a resin by transfer molding so as to substantially cover at least a surface of the substrate. In the method, a thermal expansion coefficient of the resin having a filler mixed therein is selected within a range of 15×10⁻⁶/° C. to 23×10⁻⁶/° C. so as to suppress shrinkage on curing of the resin in the molding and to form a rear surface of the substrate, after the resin is cured, to be slightly convex downward.

Generally, when considering a stress, shrinkage on curing when a liquid or a fluid sealing resin is cured to be a solid and thermal expansion and shrinkage of the resin after cured need to be considered separately.

As shown in FIG. 7B, considering expansion and shrinkage of the sealing resin, the substrate 101 and the covering resin 108 may have substantially the same thermal expansion coefficient. Accordingly, a compressive force is constantly applied to the solder. In addition, expansion and shrinkage of the substrate and expansion and shrinkage of the sealing resin coincide with each other. Thus, the stress is unlikely to be applied to the solder. Moreover, if a liquid or a fluid sealing resin is partially applied and cured to be a solid, as shown in FIG. 7B, the substrate has a sufficiently strong rigidity against the shrinkage. Thus, there is no need to consider the problem of warping.

However, considering the shrinkage on curing of the sealing resin, as shown in FIG. 7C, the more an amount (volume) of the covering resin is increased, the larger an influence of the shrinkage on curing of the sealing resin becomes. Accordingly, due to this large shrinkage, the substrate is warped.

In order to suppress this warping, in the present application, the thermal expansion coefficient of the resin is selected to be substantially the same as that of the aluminum substrate. Moreover, in order to suppress the shrinkage, a filler is mixed in the resin by about 80% thereof. This filler is originally a solid and has no shrinkage on curing. Thus, shrinkage in curing of the entire sealing resin is reduced. Considering the cured resin having the filler mixed therein, the thermal expansion coefficient thereof may be within a range of about 15×10⁻⁶/° C. to 23×10⁻⁶/° C.

Specifically, the filler may be mixed to suppress the shrinkage in curing. Moreover, the thermal expansion coefficient of the cured sealing resin having the filler mixed therein may be close to that of the aluminum substrate. However, considering an amount of the shrinkage on curing, a better balance with the expansion and shrinkage of the substrate can be achieved if the thermal expansion coefficient of the sealing resin is somewhat smaller than that of the aluminum substrate.

In an embodiment of the present invention, a sealing resin which has a thermal expansion coefficient somewhat smaller than that of a circuit board and has a filler mixed therein is used. Thus, shrinkage on curing, which is caused when the sealing resin is formed, can be reduced. Therefore, peeling and the like due to the shrinkage on curing of the sealing resin can be prevented. Furthermore, warping of the entire device is also suppressed.

Furthermore, according to a method for manufacturing a circuit device of preferred embodiment of the invention, a circuit board is slightly curved toward a rear surface thereof by shrinkage on curing of a sealing resin, and the sealing resin or the circuit board can be allowed to come into contact with a radiator. Therefore, the sealing resin or the rear surface of the circuit board can be allowed to come into close contact with the radiator. Thus, a heat releasing property can be improved.

### BRIEF DESCRIPTION OF THE DRAWINGS

FIG. 1A is a plan view, FIG. 1B is a cross sectional view and FIG. 1C is a cross sectional view, showing a hybrid integrated circuit device of preferred embodiment of the invention.

FIG. 2A is a graph showing a relationship between a thermal expansion coefficient of a sealing resin and warping of a circuit board, FIG. 2B is a cross sectional view of the hybrid integrated circuit device, and FIG. 2C is a cross sectional view of the hybrid integrated circuit device.

FIGS. 3A to 3D are cross sectional views showing a method for manufacturing a hybrid integrated circuit device of preferred embodiment of the invention.

FIGS. 4A and 4B are cross sectional views showing the method for manufacturing a hybrid integrated circuit device of preferred embodiment of the invention.

FIG. 5 is a cross sectional view showing the method for manufacturing a hybrid integrated circuit device of preferred embodiment of the invention.

FIGS. 6A and 6B are cross sectional views showing the method for manufacturing a hybrid integrated circuit device of preferred embodiment of the invention.

FIGS. 7A to 7C are cross sectional views showing conventional hybrid integrated circuit devices.

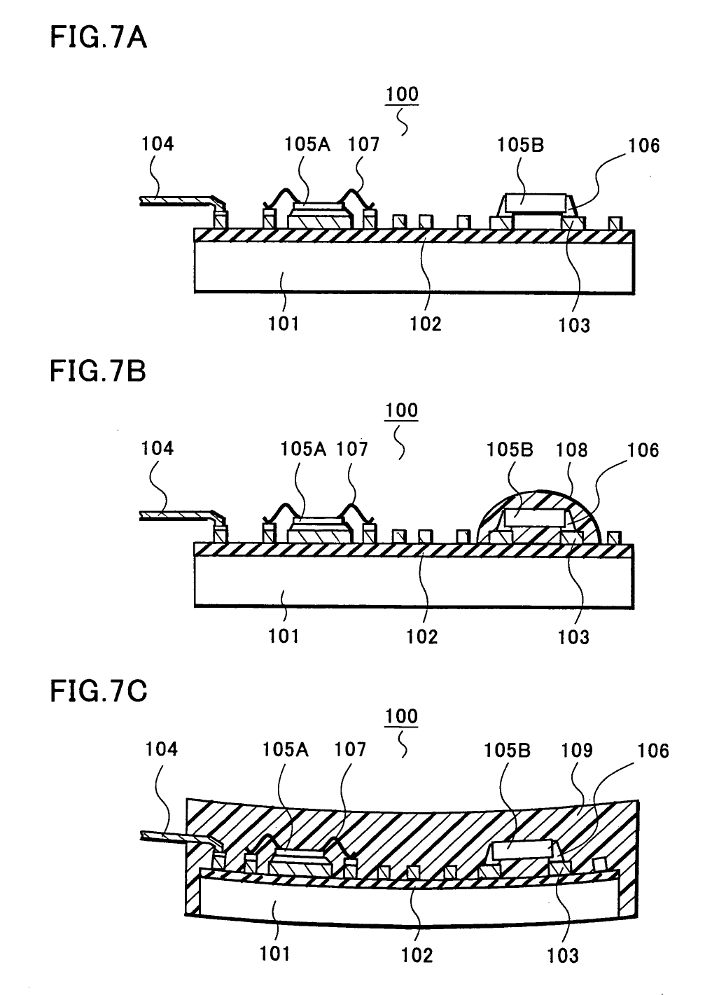

### DESCRIPTION OF THE EMBODIMENTS

Configuration of Hybrid Integrated Circuit Device 10

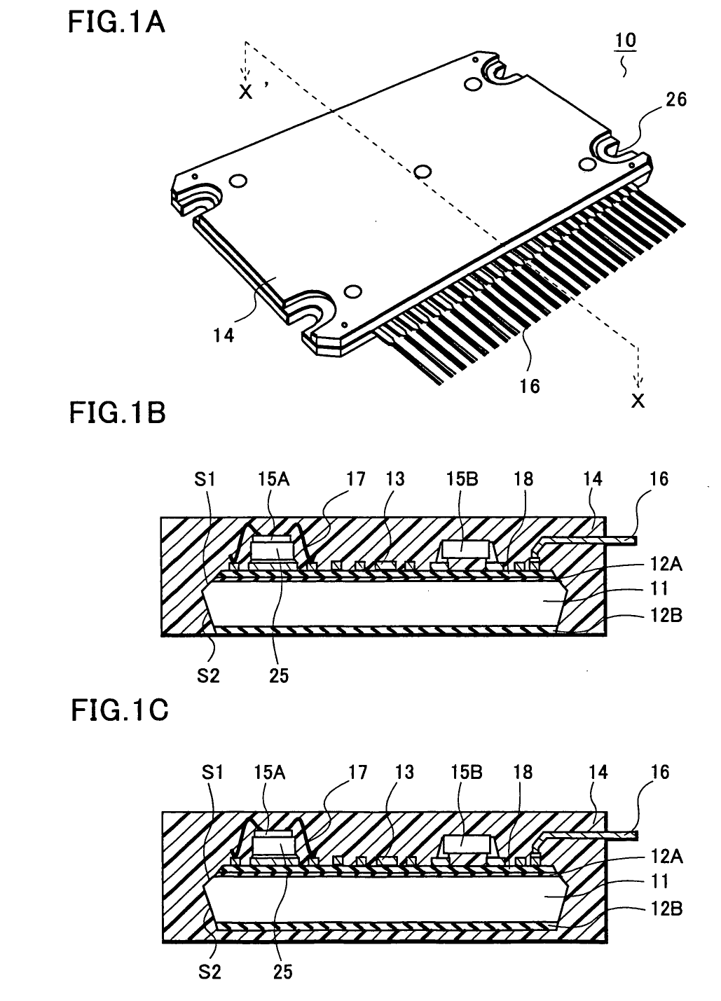

With reference to FIGS. 1A to 1C, description will be given of a configuration of a hybrid integrated circuit device 10 of preferred embodiment of the invention.

First, an insulating layer 18 is formed on a surface of a rectangular circuit board 11. Thereafter, a conductive pattern 13 having a predetermined shape is formed on a surface of the insulating layer 18. Furthermore, in predetermined spots of the conductive pattern 13, a semiconductor element 15A and a chip element 15B are electrically connected. The conductive pattern 13, the semiconductor element 15A and the chip element 15B, all of which are formed above the surface of the circuit board 11, are covered with a sealing resin 14.

The circuit board 11 is made of metal such as aluminum and copper. If aluminum is used as a material of the circuit board 11, a thermal expansion coefficient of the circuit board 11 is about 23×10⁻⁶/° C. A specific size of the circuit board 11 is, for example, about length×breadth×thickness=61 mm×42.5 mm×1.5 mm.

Each side of the circuit board 11 is formed of first and second slopes S1 and S2, and is protruded outward. The first slope S1 is continuous with an upper surface of the circuit board 11 and extended obliquely downward. The second slope S2 is continuous with a lower surface of the circuit board 11 and extended obliquely upward. According to this configuration, adhesion between the sides of the circuit board 11 and the sealing resin can be made strong. Note that the sides of the circuit board 11 may be flat.

On the surface and a rear surface of the circuit board 11, first and second oxide films 12A and 12B are formed, respectively.

The first oxide film 12A is formed so as to cover the entire surface of the circuit board 11. Specifically, a composition of the first oxide film 12A is Al₂O₃, and a thickness thereof is within a range of 1 μm to 5 μm. Formation of the first oxide film 12A on the surface of the circuit board 11 makes it possible to improve adhesion of the insulating layer 18. In this embodiment, the first oxide film 12A is formed to be very thin. Therefore, heat generated by the semiconductor element 15A and the like can be efficiently released to the outside. Moreover, the thickness of the first oxide film 12A may be 1 μm or less as long as adhesion between the insulating layer 18 and the circuit board 11 can be secured.

The second oxide film 12B is formed so as to cover the entire rear surface of the circuit board 11. The second oxide film 12B is formed of Al₂O₃ as in the case of the first oxide film 12A, and has a thickness within a range of about 7 μm to 13 μm. The second oxide film 12B plays a role of mechanically protecting the rear surface of the circuit board 11. Furthermore, the second oxide film 12B plays a role of protecting the rear surface of the circuit board 11 from an etchant in a step of patterning the conductive pattern 13 by wet etching. Therefore, the second oxide film 12B is formed to be thicker than the first oxide film 12A. Moreover, by making the second oxide film 12B thick, warping of circuit elements 15 due to shrinkage on curing of the sealing resin 14 can be also reduced.

The insulating layer 18 is formed so as to cover the entire surface of the circuit board 11. The insulating layer 18 is made of an expoxy resin filled with a large amount of filler such as Al₂O₃. Filling of the filler reduces a thermal resistance of the insulating layer 18. Therefore, heat generated by the circuit elements mounted is suitably released to the outside through the circuit board 11.

The conductive pattern 13 is made of metal such as copper, and is formed on the surface of the insulating layer 18 so as to realize a predetermined electrical circuit. Moreover, on a side from which leads 16 are derived, pads formed of the conductive pattern 13 are formed.

The circuit elements including the semiconductor element 15A and the chip element 15B are fixed to predetermined spots of the conductive pattern 13 by use of a bond such as solder. As the semiconductor element 15A, a transistor, an LSI chip, a diode or the like is employed. Here, the semiconductor element 15A is connected to the conductive pattern 13 through thin metal wires 17. As the chip element 15B, a chip resistor, a chip condenser or the like is employed. Electrodes on both ends of the chip element 15B are fixed to the conductive pattern 13 by use of the bond such as solder. Moreover, as the chip element 15B, an element having electrode parts on both ends thereof, such as an inductance, a thermistor, an antenna and an oscillator, is employed. Furthermore, a plastic molded package and the like can also be fixed to the conductive pattern 13 as the circuit element.

As the bond that joins the circuit elements, solder, a conductive paste or the like is employed. Here, as the solder, lead eutectic solder or lead-free solder can be used. As the conductive paste, a Ag paste, a Cu paste or the like is employed.

If the circuit elements are fixed by use of the lead-free solder, it is required to pay attention to occurrence of a crack due to a thermal stress. This is because the lead-free solder is a material which has a large Young's modulus and is susceptible to cracks. As an example, a Young's modulus of the lead eutectic solder is 25.8 GPa whereas the Young's modulus of the lead-free solder having a composition of Sn-3.0Ag-0.5Cu is 41.6 GPa. As the lead-free solder, specifically, a Sn—Ag base, a Sn—Ag—Cu base, a Sn—Cu base, a Sn—Zn base or one having a composition in which Bi or In is added to any of those bases can be employed.

The leads 16 are fixed to the pads provided in a peripheral part of the circuit board 11, and have a function of performing input-output with the outside. Here, a number of the leads 16 are provided on one side. The leads 16 can also be derived from four sides of the circuit board 11 or from two sides facing each other.

The sealing resin 14 is formed by transfer molding using a thermosetting resin. In FIG. 1B, the conductive pattern 13, the semiconductor element 15A, the chip element 15B and the thin metal wires 17 are sealed by use of the sealing resin 14. Accordingly, the surface and the sides of the circuit board 11 are covered with the sealing resin 14. The rear surface of the circuit board 11 is exposed to the outside from the sealing resin 14. Moreover, as shown in FIG. 1C, the entire circuit board 11 including the rear surface thereof may be covered with the sealing resin 14. Furthermore, since the sealing resin 14 made of a thermosetting resin shrinks when cured, a compressive stress is continuously applied to the circuit elements, the solder and the like.

In this embodiment, the sealing resin having substantially the same thermal expansion coefficient as that of the circuit board 11 is selected, and a filler such as aluminum oxide is mixed into the resin. Thus, a volume of the resin itself is reduced, and, accordingly, shrinkage of the resin when cured is suppressed. For example, the filler is mixed in the sealing resin 14 by about 80 wt %.

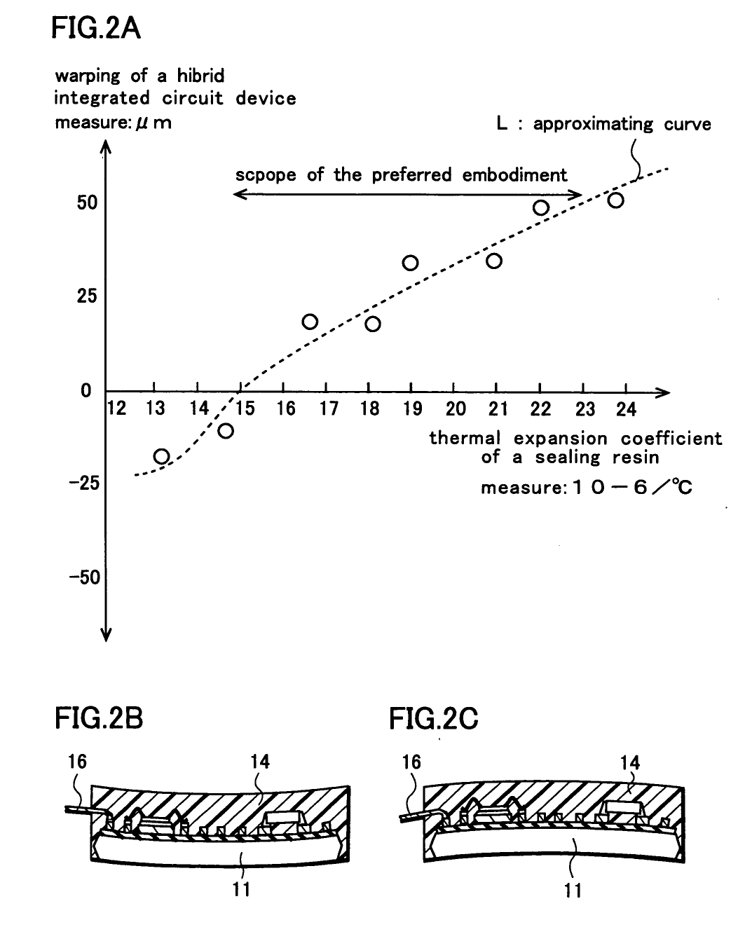

Moreover, the circuit board is pressurized by screws or the like at both sides thereof and mounted. Thus, as shown in FIG. 2B, the circuit board is required to have a shape slightly convex downward at normal temperature after curing.

In this embodiment, the thermal expansion coefficient of the sealing resin 14 having the filler mixed therein is set to be smaller than the thermal expansion coefficient of the circuit board 11. Thus, warping of the circuit board 11 due to shrinkage on heat curing of the sealing resin 14 can be reduced. Moreover, it is possible to allow the circuit board 11 after curing to be slightly convex downward. Furthermore, expansion and shrinkage of the sealing resin 14 due to heat in mounting are allowed to approximate those of the circuit board 11 as much as possible. Thus, cracks in solder material and the like can also be suppressed.

As described in the section of the background art, when an aluminum substrate is used as the circuit board 11, there is a large difference in the thermal expansion coefficient between the circuit board 11 and the chip element 15B. Therefore, a large thermal stress acts on solder which connects the circuit board to the chip element. Accordingly, the thermal expansion coefficient of the sealing resin 14 is set to about 23×10⁻⁶/° C., which is equal to that of the circuit board 11. Thus, the thermal stress is reduced.

However, the thermosetting resin shrinks when heat cured. Therefore, when the sealing resin 14 having the thermal expansion coefficient of about 23×10⁻⁶/° C. or more is used, an amount of shrinkage due to heat curing is increased. Accordingly, a problem of excessive warping of the circuit board 11 may occur.

Consequently, in this embodiment, the shrinkage of the resin when cured is suppressed by mixing the filler into the resin, and the thermal expansion coefficient of the sealing resin 14 having the filler mixed therein is set within a range of 15×10⁻⁶/° C. to 23×10⁻⁶/° C. Thus, the warping of the circuit board 11 in heat curing can be prevented while connection reliability of the circuit elements is secured. According to experiments, if the thermal expansion coefficient of the resin having the filler mixed therein is set within the foregoing range, connection reliability of the circuit elements 15 can be set to be equal to that in the case where the thermal expansion coefficient of the sealing resin 14 is 23×10⁻⁶/° C. Furthermore, warping of the device of this embodiment can be reduced.

With reference to FIGS. 2A to 2C, description will be given of a relationship between the thermal expansion coefficient of the sealing resin 14 and warping of the hybrid integrated circuit device 10. FIG. 2A is a graph showing the relationship therebetween. FIGS. 2B and 2C are cross sectional views of the hybrid integrated circuit device 10 when warped.

The horizontal axis of the graph shown in FIG. 2A indicates the thermal expansion coefficient of the sealing resin 14 having the filler mixed therein. The vertical axis thereof indicates an amount of the warping of the hybrid integrated circuit device 10. Here, an amount of the filler mixed is adjusted, and plastic molding and heat curing of a plurality of the hybrid integrated circuit devices 10 are performed by use of the sealing resins 14 having different thermal expansion coefficients. Thereafter, amounts of warping of the respective hybrid integrated circuit devices 10 are measured. A specific method for measuring the amount of warping is as follows. Specifically, first, the heat-cured hybrid integrated circuit device 10 is placed on a flat surface. Thereafter, a height of an upper surface of the hybrid integrated circuit device 10 is measured, and a difference in height is set to be the amount of warping of the hybrid integrated circuit device 10. The respective points indicated by outline circles show experimental results. The dotted curve is an approximating curve L calculated from these experimental results.

From the experimental results shown in the graph, it can be understood that use of a sealing resin (with less filler) which has a large thermal expansion coefficient increases the amount of warping of the hybrid integrated circuit device 10. For example, use of the sealing resin (with more filler) 14 having a thermal expansion coefficient of about 15×10⁻⁶/° C. makes it possible to obtain the flat hybrid integrated circuit device 10 without warping. Moreover, along with an increase in the thermal expansion coefficient of the sealing resin 14, an amount of warping of the device is also increased.

When the thermal expansion coefficient of the sealing resin 14 is about 15×10⁻⁶/° C. or more, the amount of warping takes a positive value. Along with the increase in the thermal expansion coefficient, the warping of the hybrid integrated circuit device 10 becomes larger. When the amount of warping takes a positive value, a shape of cross section as shown in FIG. 2B is formed. Specifically, the circuit board 11 included in the hybrid integrated circuit device 10 is curved toward the rear surface thereof. In addition, the entire device is curved so as to be convex downward. With this shape of cross section, the entire device can be flattened by pressing down both ends of the device.

To be more specific, with reference to FIG. 1A, fixation parts 26 are provided in a periphery of the sealing resin 14. By pressing down the fixation parts 26 with fixing means such as screws, the entire hybrid integrated circuit device 10 can be flattened.

When the thermal expansion coefficient of the sealing resin 14 having the filler mixed therein is 15×10⁻⁶/° C. or less, the amount of warping takes a negative value. If the amount of warping is negative, a shape of cross section of the hybrid integrated circuit device 10 becomes a state as shown in FIG. 2C. Specifically, the entire device is curved so as to be convex upward. In this state, even if the both ends of the device are pressed down, the entire device is not flattened. Even if a rear surface of the hybrid integrated circuit device 10 is allowed to come into contact with a radiation fin or the like, there is formed a gap therebetween. Therefore, a heat releasing property of the hybrid integrated circuit device 10 is lowered.

In this embodiment, the thermal expansion coefficient of the sealing resin 14 having the filler mixed therein is set within a range of 15×10⁻⁶/° C. to 23×10⁻⁶/° C.

By setting the thermal expansion coefficient of the sealing resin 14 to 23×10⁻⁶/° C. or less, the amount of warping of the hybrid integrated circuit device 10 can be set constant or less. Moreover, a stress caused by shrinkage on curing can be reduced by mixing the filler into the resin. Therefore, breakdown of the electrical circuit in the device due to the shrinkage on curing can be suppressed. Furthermore, expansion and shrinkage of the sealing resin 14 due to a temperature change after curing are equal to those of the circuit board 11. Thus, reliability is improved. Particularly, a compressive stress constantly acts on connection parts made of solder material such as solder. Thus, occurrence of cracks can be suppressed.

Furthermore, by setting the thermal expansion coefficient of the sealing resin 14 having the filler mixed therein to 15×10⁻⁶/° C. or more, it is possible to suppress warping of the hybrid integrated circuit device 10 so as to be convex upward. Specifically, it is possible to prevent the hybrid integrated circuit device 10 from having the shape of cross section as shown in FIG. 2C. If such warping as shown in FIG. 2C occurs, the rear surface of the device does not come into contact with the radiator. Thus, the heat releasing property is lowered.

Method for Manufacturing Hybrid Integrated Circuit Device 10

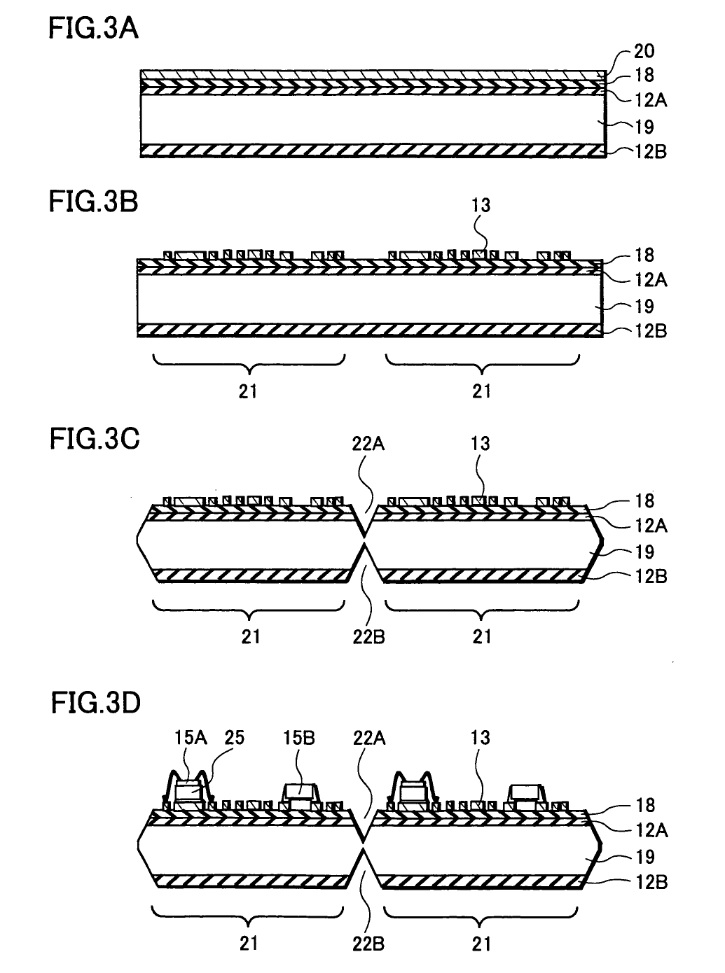

With reference to FIGS. 3 to 6, a method for manufacturing a hybrid integrated circuit device will be described.

With reference to FIG. 3A, first, a conductive foil 20 is attached to a surface of a metal substrate 19 with an insulating layer 18 interposed therebetween. A first oxide film 12A is formed entirely on the surface of the metal substrate 19. Therefore, by electrical connection between the first oxide film 12A and the insulating layer 18, the insulating layer 18 and the metal substrate 19 are bonded together. Furthermore, the conductive foil 20 is patterned by wet etching, and a conductive pattern 13 is formed. Etching of the conductive foil 20 is performed by immersing the entire metal substrate 19 in an etchant.

FIG. 3B shows a cross section of the metal substrate 19 after the conductive pattern 13 is formed. Here, on the surface of the metal substrate 19, a plurality of units 21 including the conductive pattern 13 are formed. Here, the unit means a region forming one hybrid integrated circuit device. The plurality of units 21 may be formed in a matrix manner.

With reference to FIG. 3C, next, in the surface and a rear surface of the metal substrate 19, first and second trenches 22A and 22B are formed, respectively. The first and second trenches 22A and 22B are formed by use of a cut saw rotating at a high speed.

With reference to FIG. 3D, subsequently, circuit elements are electrically connected to the conductive pattern 13. Here, the circuit elements such as a semiconductor element 15A and a chip element 15B are fixed to the conductive pattern 13 by use of solder or the like. Moreover, electrodes on a surface of the semiconductor element 15A are electrically connected to the conductive pattern 13 through thin metal wires. Furthermore, the semiconductor element 15A may be placed on an upper surface of a heat sink 25 fixed to the conductive pattern 13.

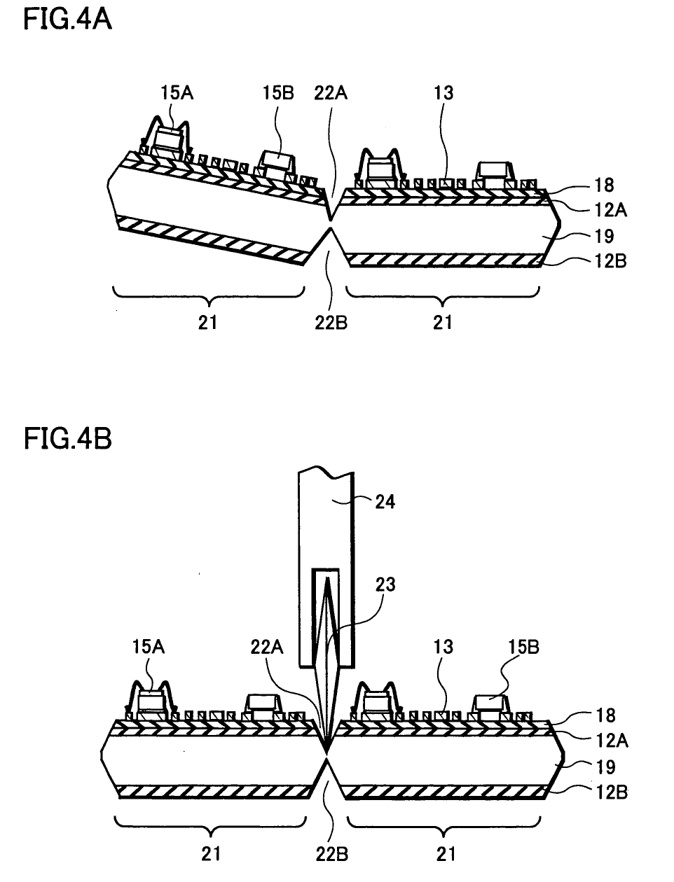

With reference to FIGS. 4A and 4B, next, description will be given of a step of dividing the metal substrate 19. As a method for dividing the metal substrate 19, two methods can be employed, including a dividing method by “bending” and a dividing method by “cutting”.

With reference to FIG. 4A, description will be given of a method for dividing the metal substrate 19 by “bending”. Here, a spot where the first and second trenches 22A and 22B are formed is set to be a point of support, and the metal substrate 19 is bent. In FIG. 4A, the unit 21 positioned on the right side of the page space is fixed, and the unit 21 positioned on the left side is bent. This bending is performed more than once in an up-and-down direction to separate the units 21 from each other. In this embodiment, on a boundary between the units 21, the first and second trenches 22A and 22B are formed. Therefore, the respective units 21 are connected to each other only by thick portions where no trenches are formed. Thus, division by “bending” described above can be easily performed.

With reference to FIG. 4B, description will be given of a method for dividing the metal substrate 19 by cutting. Here, by rotating a cutter 23 while pressing the cutter against the first trench 22A, the metal substrate 19 is divided. The cutter 23 has a disc-like shape, and a circumferential edge thereof takes the form of an acute angle. A center portion of the cutter 23 is fixed to a supporting part 24 so that the cutter 23 can be freely rotated. Specifically, the cutter 23 has no driving force. By moving the cutter 23 while pressing the cutter against a bottom of the first trench 22A, the cutter 23 is rotated, and the metal substrate 19 is divided. According to this method, conductive dust caused by cutting is not generated. Therefore, short-circuiting caused by this dust can be prevented.

Note that the metal substrate 19 can also be divided by use of methods other than that described above. To be more specific, the metal substrate 19 can be divided by punching, shearing and the like by use of a pressing machine.

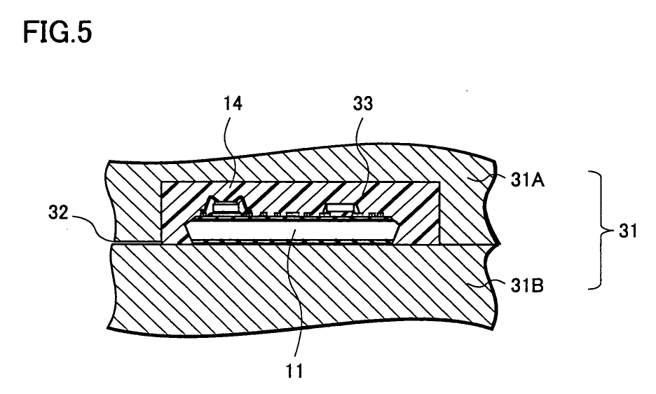

With reference to FIG. 5, next, a sealing resin 14 is formed so as to cover at least the surface of a circuit board 11. Here, the sealing resin 14, which has the filler mixed therein and is made of the thermosetting resin, is formed by transfer molding using a mold 31. Specifically, the circuit board 11 is housed in a cavity 33 of the mold 31, and the sealing resin 14 is injected into the cavity 33 from a gate 32.

When the sealing resin 14 is injected, the mold 31 is heated to about 170° C. Therefore, the sealing resin 14 made of the thermosetting resin is heat cured as injected into the cavity 33. This heat curing is performed for about several ten seconds to one hundred seconds. By performing the heat curing, the sealing resin 14 shrinks. However, the thermal expansion coefficient of the sealing resin 14 is 23×10⁻⁶/° C. or less, and an amount of shrinkage on curing is reduced. Thus, excessive warping of the circuit board 11 due to the shrinkage on curing is suppressed.

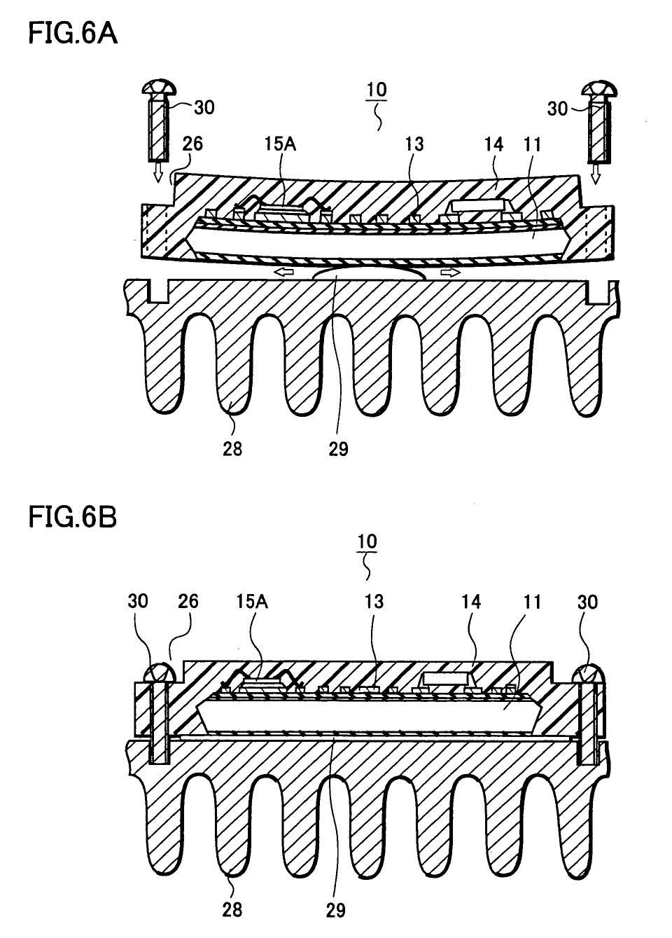

With reference to FIGS. 6A and 6B, next, a hybrid integrated circuit device 10 is allowed to come into contact with a radiation fin 28. First, as shown in FIG. 6A, a grease 29 is applied to an upper surface of the radiation fin 28, the upper surface being formed to be flat. The radiation fin 28 is made of metal such as copper, and has a function of releasing heat generated by the hybrid integrated circuit device 10 to the outside. Moreover, the grease 29 is interposed between the rear surface of the hybrid integrated circuit device 10 and the upper surface of the radiation fin 28, and has a function of improving the heat releasing property. The grease 29 is applied to a spot corresponding to a center portion of the hybrid integrated circuit device 10.

Next, after the hybrid integrated circuit device 10 is placed on an upper part of the radiation fin 28, the rear surface there of is allowed to come into contact with the upper surface of the radiation fin 28. To be more specific, a fixation parts 26 provided at the both ends of the hybrid integrated circuit device 10 are pressed down by screws 30. Thus, the rear surface of the hybrid integrated circuit device 10 is bonded to the upper part of the radiation fin 28. By heat curing the sealing resin 14, the hybrid integrated circuit device 10 is curved so as to protrude downward. Therefore, a pressing force of the screws 30 flattens the curved hybrid integrated circuit device 10. Thus, the grease 29 applied to the center portion can be spread to the peripheral part. Moreover, the pressing force of the screws 30 fixes the hybrid integrated circuit device 10 in a manner that curve thereof is reduced. Thus, the rear surface of the hybrid integrated circuit device 10 is bonded to the upper surface of the radiation fin 28.

With reference to FIG. 6B, by pressing the peripheral part of the hybrid integrated circuit device 10 by use of the screws 30, the rear surface of the hybrid integrated circuit device 10 is bonded to the upper surface of the radiation fin 28. Therefore, heat generated by the circuit elements included in the hybrid integrated circuit device 10 is released to the outside through the radiation fin 28. In FIG. 6B, the rear surface of the circuit board 11, which is exposed from the sealing resin 14, comes into contact with the upper surface of the radiation fin 28. However, as shown in FIG. 1C, the sealing resin 14 may be formed so as to cover the rear surface of the circuit board 11. In this case, the rear surface of the hybrid integrated circuit device 10, which is formed of the sealing resin 14, comes into contact with the upper surface of the radiation fin 28.

What is claimed is:

1. A circuit device which includes a conductive pattern provided on a surface of a circuit board, circuit elements electrically connected to the conductive pattern, and a sealing resin which seals the circuit elements by covering at least the surface of the circuit board, wherein
a thermal expansion coefficient of the sealing resin is set to be smaller than a thermal expansion coefficient of the circuit board in a manner that a filler is mixed in the resin.

2. The circuit device according to claim 1, wherein a rear surface of the circuit board is exposed from the sealing resin.

3. The circuit device according to claim 1, wherein the sealing resin is formed by transfer molding.

4. The circuit device according to claim 1, wherein the circuit board is made of aluminum, and the thermal expansion coefficient of the sealing resin is set within a range of 15×10⁻⁶/° C. to 23×10⁻⁶/° C. in a manner that the filler is mixed in the resin.

5. The circuit device according to claim 1, wherein the circuit elements are fixed to the conductive pattern by use of lead-free solder.

6. A method for manufacturing a circuit device, comprising the steps of forming an electrical circuit on a surface of a circuit board, the electrical circuit including a conductive pattern and circuit elements; and
covering at least the surface of the circuit board with a sealing resin having a filler mixed therein so as to cover the circuit elements,
wherein the sealing resin having a thermal expansion coefficient smaller than that of the circuit board is used.

7. A method for manufacturing a circuit device, comprising:
forming an electrical circuit on a surface of a circuit board, the electrical circuit including a conductive pattern and circuit elements;
covering at least the surface of the circuit board with a sealing resin having a filler mixed therein so as to cover the circuit elements;
curing the sealing resin in a manner that the circuit board is curved toward a rear surface thereof by heating the sealing resin; and
allowing any of the sealing resin and the rear surface of the circuit board to come into contact with a surface of a radiator in a manner that curve of the circuit board is reduced.

8. The method for manufacturing a circuit device according to claim 6, wherein the sealing resin is a thermosetting resin formed by transfer molding.

9. The method for manufacturing a circuit device according to claim 7, wherein the sealing resin is a thermosetting resin formed by transfer molding.

10. The method for manufacturing a circuit device according to claim 6, wherein a thermal expansion coefficient of the sealing resin is set to be smaller than that of the circuit board.

11. The method for manufacturing a circuit device according to claim 7, wherein a thermal expansion coefficient of the sealing resin is set to be smaller than that of the circuit board.

12. The method for manufacturing a circuit device according to claim 6, wherein the circuit board is made of aluminum, and a thermal expansion coefficient of the sealing resin is set within a range of 15×10⁻⁶/° C. to 23×10⁻⁶/° C.

13. The method for manufacturing a circuit device according to claim 7, wherein the circuit board is made of aluminum, and a thermal expansion coefficient of the sealing resin is set within a range of 15×10⁻⁶/° C. to 23×10⁻⁶/° C.

14. A method for manufacturing a circuit device, comprising the steps of:
preparing a substrate made of any of aluminum and copper, on which a conductive pattern mainly made of copper is formed;
mounting circuit elements on the substrate; and
forming a resin by transfer molding so as to substantially cover at least a surface of the substrate,
wherein a thermal expansion coefficient of the resin having a filler mixed therein is selected within a range of 15×10⁻⁶/° C. to 23×10⁻⁶/° C. so as to suppress shrinkage on curing of the resin in the molding and to form a rear surface of the substrate, after the resin is cured, to be slightly convex downward.
